(19) United States
(12) Patent Application Publication
(10) Pub. No.: US 2026/0076011 A1
(43) Pub. Date: Mar. 12, 2026

(54) DISPLAY MODULE AND METHOD FOR MANUFACTURING THE SAME

(71) Applicant: Qisda Corporation, Taoyuan City (TW)

(72) Inventor: Po-Fu WU, Taoyuan City (TW)

(73) Assignee: Qisda Corporation, Taoyuan City (TW)

(21) Appl. No.: 19/269,298

(22) Filed: Jul. 15, 2025

(30) Foreign Application Priority Data
Sep. 12, 2024 (CN) 202411278327.5

(51) Int. Cl. H10H 29/855; H01L 25/075; H10H 29/01; H10H 29/853; H10H 29/854

(52) U.S. Cl. CPC H10H 29/8552; H10H 29/0362; H10H 29/0363; H10H 29/853; H10H 29/854; H10W 90/00

(57) ABSTRACT

A display module is provided. The display module includes a circuit board, a plurality of pixel structures and a light blocking layer. The pixel structures are disposed on the circuit board. Each of the pixel structures includes a plurality of light-emitting diode chips and a protection layer. The light-emitting diode chips are disposed on the circuit board. The protection layer encases the light-emitting diode chips. The light blocking layer is disposed on the circuit board and surrounds the pixel structures.

This application claims the benefit of People's Republic of China application Serial No. 202411278327.5, filed Sep. 12, 2024, the subject matter of which is incorporated herein by reference.

### BACKGROUND

### Technical Field

The present disclosure relates to a display module and a method for manufacturing the same, and more particularly to a display module using light-emitting diode chips and a method for manufacturing the same.

### Description of the Related Art

In recent years, direct-view light-emitting diode (DVLED) displays have been developed, and DVLED displays utilize the light-emitting diodes themselves to create images. As compared with traditional liquid crystal displays, DVLED displays can provide larger, brighter, and higher-contrast images. Generally, a DVLED display is formed by small light boards. Each small light board may include hundreds of thousands or even millions of light-emitting diode chips. For aesthetic purposes, a black adhesive needs to be applied to the spaces between these light-emitting diode chips to form a light blocking layer. If the black adhesive is misapplied to certain light-emitting diode chips, it can be removed using methods such as lasers. However, if too many chips are covered by the black adhesive, the light board must be scrapped.

However, the size of the light-emitting diode chip is very small, and the scheduled height of the light-emitting diode chip is mostly only 80˜85 micrometers (μm). In addition, light-emitting diode chips of different colors, even if they are produced by the same manufacturer and have the same model, may have different standard sizes due to different manufacturing processes. Moreover, the scheduled allowable tolerance range for the chip often reaches up to ±10 μm to ±15 μm, and the error of the acquired chip may even be as high as ±20 μm to ±30 μm. In other words, the heights of the light-emitting diode chips actually placed on the small light board may vary greatly. In this case, it is difficult to prevent the misapplication of black adhesive, the product yield is difficult to improve, and the production cost is difficult to reduce.

### SUMMARY

The purpose of the present disclosure is to prevent the above problems.

According to an embodiment of the present disclosure, a display module is provided. The display module includes a circuit board, a plurality of pixel structures and a light blocking layer. The pixel structures are disposed on the circuit board. Each of the pixel structures includes a plurality of light-emitting diode chips and a protection layer. The light-emitting diode chips are disposed on the circuit board. The protection layer encases the light-emitting diode chips. The light blocking layer is disposed on the circuit board and surrounds the pixel structures.

According to another embodiment of the present disclosure, a method for manufacturing a display module is provided. The method includes the following steps. First, a plurality of light-emitting diode chips of a plurality of pixel structures are provided on a circuit board. Then, a plurality of protection layers are formed to encase the light-emitting diode chips. Each of the protection layers belongs to a pixel structure of the pixel structures and encases the light-emitting diode chips of the pixel structure. Then, a light blocking layer on the circuit board and surrounding the pixel structures is formed.

Providing the protection layer can prevent the black adhesive used to form the light blocking layer from being misapplied to the light-emitting diode chip, thereby improving the yield and reducing the production cost.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a schematic view of a display module according to the present disclosure.

FIG. 2 shows a schematic view of another display module according to the present disclosure.

FIG. 3 is a flow chart showing a method for manufacturing a display module according to the present disclosure.

FIGS. 4A to 4I show schematic views at different stages of a method for manufacturing a display module according to the present disclosure.

### DETAILED DESCRIPTION

Various embodiments will be described more fully hereinafter with reference to accompanying drawings. The description herein and the accompanying drawings are provided for illustrative only, and not intended to result in a limitation. For clarity, the components may not be drawn to scale. In addition, some components and/or reference numerals may be omitted from some drawings. It is contemplated that the elements and features of one embodiment can be beneficially incorporated in another embodiment without further recitation.

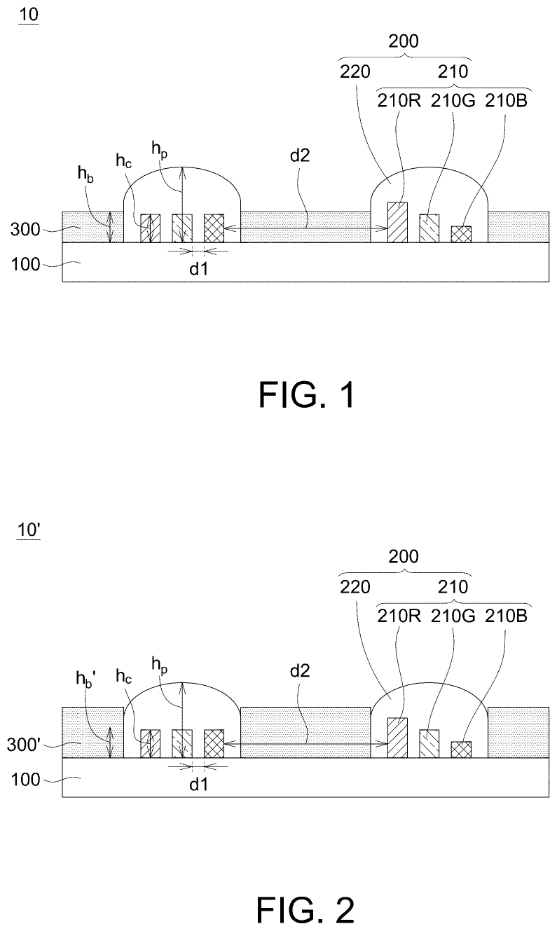

Referring to FIG. 1, FIG. 1 shows a display module 10 according to the present disclosure. The display module 10 includes a circuit board 100, a plurality of pixel structures 200 and a light blocking layer 300. The pixel structures 200 are disposed on the circuit board 100. Each of the pixel structures 200 includes a plurality of light-emitting diode chips 210 and a protection layer 220. The light-emitting diode chips 210 are disposed on the circuit board 100. The protection layer 220 encases the light-emitting diode chips 210. The light blocking layer 300 is disposed on the circuit board 100 and surrounds the pixel structures 200.

Specifically, the circuit board 100 may be a printed circuit board. The circuits for the light-emitting diode chips 210 and/or other related electronic devices may be disposed on the circuit board. However, it can be understood that the present disclosure is not limited thereto.

The light-emitting diode chips 210 of each of the pixel structures 200 may include light-emitting diode chips 210 of different colors. For example, the light-emitting diode chips 210 of each of the pixel structures 200 can consist of a red light-emitting diode chip 210R, a green light-emitting diode chip 210G and a blue light-emitting diode chip 210B. In this case, in each of the pixel structures 200, the red light-emitting diode chip 210R, the green light-emitting diode chip 210G and the blue light-emitting diode chip 210B are all encased by the same protection layer 220. However, it can be understood that the light-emitting diode chips 210 of each of the pixel structures 200 can also be a combination of light-emitting diode chips of other numbers and/or other colors. In some embodiment, at least two of the light-emitting diode chips 210 of at least one of the pixel structures 200 have different heights. For example, in FIG. 1, the light-emitting diode chips 210 of the pixel structure 200 on the left are shown to have the same height, and the light-emitting diode chips 210 of the pixel structure 200 on the right are shown to have three different heights. According to some embodiments, at least two of the light-emitting diode chips 210 of at least one of the pixel structures 200 can have different lateral sizes, that is, can have different lengths and/or different widths. According to some embodiments, the size of the light-emitting diode chip 210 is less than or equal to 250 μm, that is, the length, width and height of the light-emitting diode chip 210 is less than or equal to 250 μm.

In an example, the size of the red light-emitting diode chip can be 93(±15) μm×150(±15) μm×80(±10) μm, and the sizes of the green and blue light-emitting diode chips can be 89(±15) μm×150(±15) μm×80(±10) μm. In another example, the sizes of the red, green and blue light-emitting diode chips can all be 100(±15) μm×200(±15) μm×80(±10) μm. In yet another example, the size of the red light-emitting diode chip can be 92(±25) μm×185(±25) μm×80(±10) μm, and the sizes of the green and blue light-emitting diode chips can be 92(±25) μm×187(±25) μm×85(±15) μm. In yet another example, the size of the red light-emitting diode chip can be 100(±25) μm×200(±25) μm×85(±10) μm, and the sizes of the green and blue light-emitting diode chips can be 100(±38) μm×203(±38) μm×85(±15) μm. However, it can be understood that the present disclosure is not limited thereto.

The light-emitting diode chips 210 may be disposed by pixel. In this case, as shown in FIG. 1, a distance d1 between two adjacent light-emitting diode chips 210 of the light-emitting diode chips 210 belonging to the same pixel structure 200 of the pixel structures 200 is less than a distance d2 between two adjacent light-emitting diode chips 210 of the light-emitting diode chips 210 belonging to different pixel structures 200 of the pixel structures 200. In other words, the light-emitting diode chips 210 belonging to the same pixel structure 200 are disposed in a more compact manner. This facilitates the formation of the protection layer 220 on all the light-emitting diode chips 210 belonging to the same pixel structure 200. The light-emitting diode chip 210 may have a standard height h_{c}. Here, the standard height h_{c} can be a scheduled height provided by the manufacturer. If the light-emitting diode chips 210 of different colors have different scheduled heights, an average value can be used. However, it can be understood that the present disclosure is not limited thereto. For example, the standard height h_{c} can be determined according to design requirements.

In each of the pixel structures 200, the protection layer 220 directly contacts the light-emitting diode chips 210. According to some embodiments, the protection layer 220 can be bell-shaped. A height hₚ of the protection layer 220 may be the maximum height of the bell-shaped structure, which may be, for example, approximately twice the standard height h_{c} of the light-emitting diode chip 210; the present disclosure is not limited thereto. In some embodiments, the protection layers 220 are transparent. In other embodiments, the protection layers 220 are translucent. The material of the protection layer 220 may be epoxy resin or silicone, but the present disclosure is not limited thereto.

The light blocking layer 300 is disposed around the pixel structures 200 to prevent lateral light leakage. The light blocking layer 300 may directly contact the protection layer 220. A height h_{b} of the light blocking layer 300 may be greater than or equal to the standard height h_{c} of the light-emitting diode chip 210 and less than the height hₚ of the protection layer 220. As long as the height h_{b} of the light blocking layer 300 falls within the above range, there is no need to particularly limit the height h_{b} of the light blocking layer 300. For example, in FIG. 1, the height h_{b} of the light blocking layer 300 is slightly greater than the standard height h_{c} of the light-emitting diode chip 210. In the display module 10′ of FIG. 2, the light blocking layer 300′ has a greater height, and the height h_{b}′ of the light blocking layer 300′ is greater than heights of all the light-emitting diode chips 210 and is approximately equal to a height of the sidewall of the protection layer 220. The light blocking layer 300 may be opaque. The material of the light blocking layer 300 may be epoxy resin, silicone, or acrylic, but the present disclosure is not limited thereto.

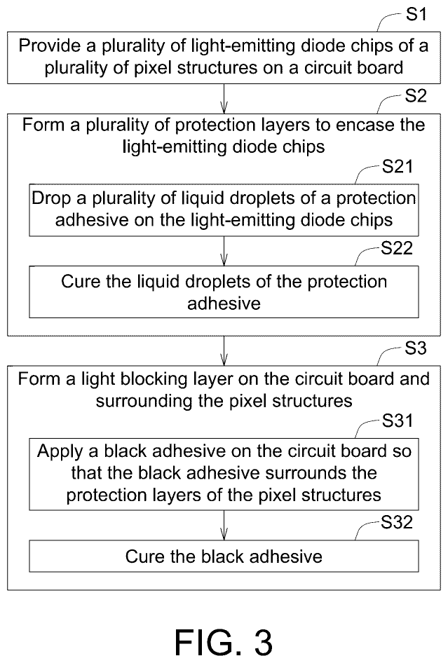

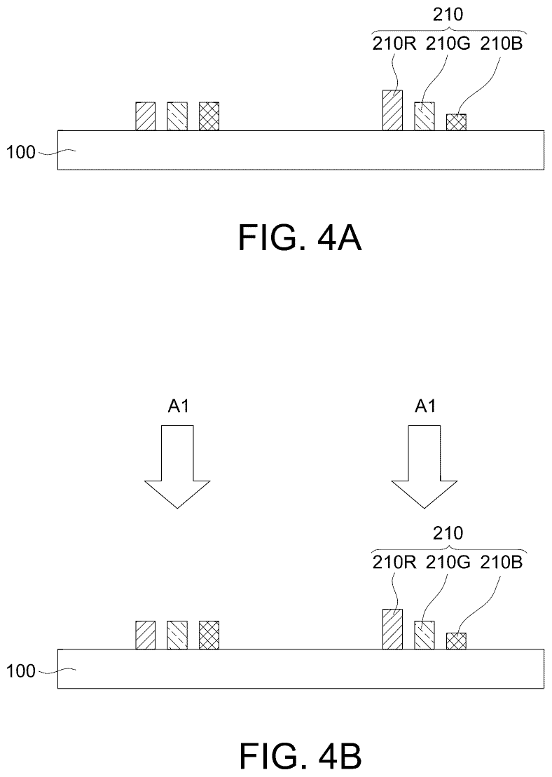

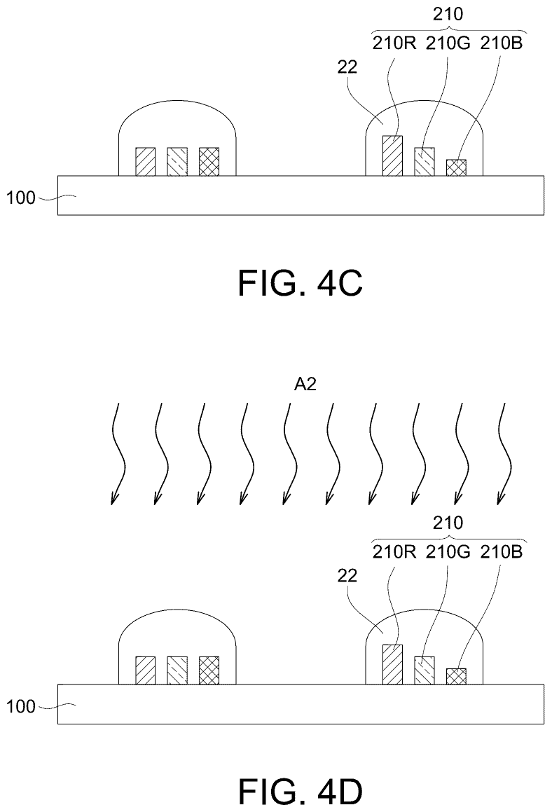

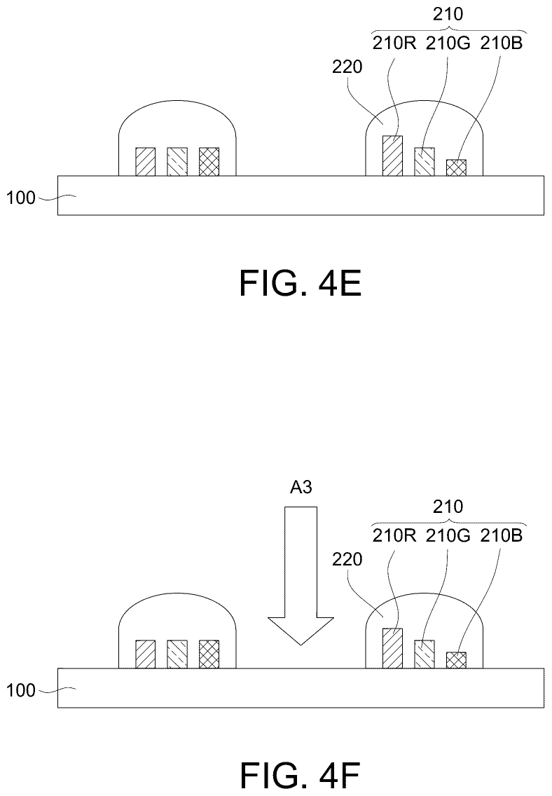

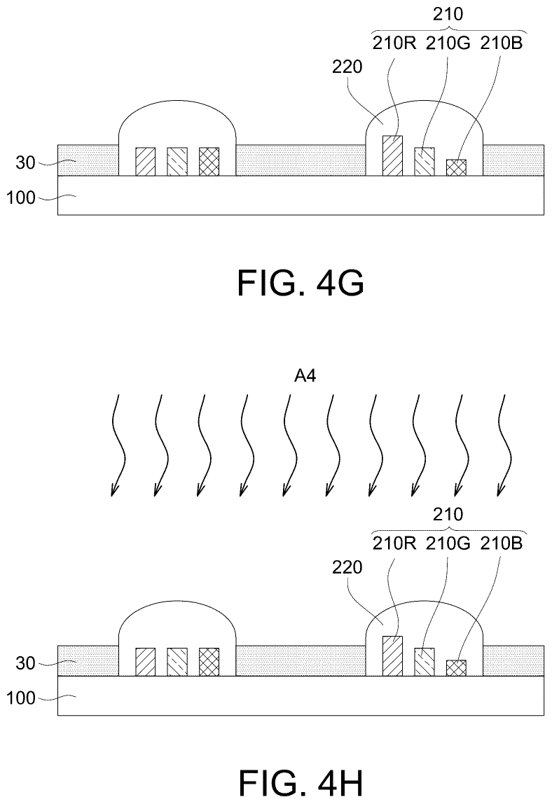

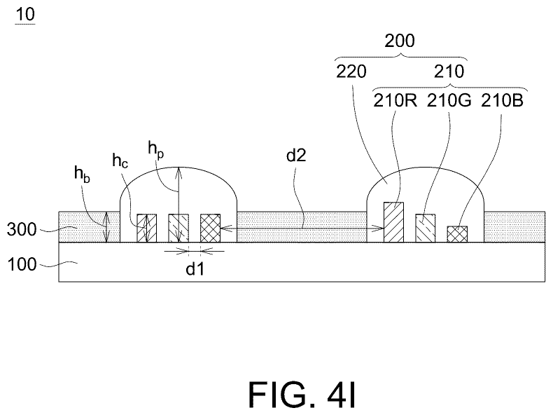

Referring to FIG. 3 and FIGS. 4A-4I, a method for manufacturing a display module according to the present disclosure will be described. FIG. 3 is a flow chart showing a method for manufacturing a display module according to the present disclosure. FIGS. 4A to 4I show schematic views at different stages of a method for manufacturing a display module according to the present disclosure.

In step S1, as shown in FIG. 4A, a plurality of light-emitting diode chips 210 of a plurality of pixel structures 200 are provided on a circuit board 100.

In step S2: a plurality of protection layers 220 are formed to encase the light-emitting diode chips 210. Each of the protection layers 220 belongs to a pixel structure 200 of the pixel structures 200 and encases the light-emitting diode chips 210 of the pixel structure 200.

Specifically, please refer to FIG. 4B, in step S21, as indicated by arrow A1, a plurality of liquid droplets 22 of a protection adhesive (shown in FIG. 4C) are dropped on the light-emitting diode chips 210. The protection adhesive may be epoxy resin or silicone, but the present disclosure is not limited thereto. The protection adhesive may be transparent or translucent, and the transparency of the protection adhesive can be adjusted according to the needs. The protection adhesive may be dispensed by a nozzle, but the present disclosure is not limited thereto. As shown in FIG. 4C, each of the liquid droplets 22 is dropped on the light-emitting diode chips 210 of one of the pixel structures 200. Then, please refer to FIG. 4D, in step S22, as indicated by arrow A2, the liquid droplets 22 of the protection adhesive are cured, for example, a thermal curing or ultraviolet curing may be performed. In some embodiments, the cured liquid droplets 22 are bell-shaped. The cured liquid droplets form the protection layer 220.

Then, in step S3, a light blocking layer 300 on the circuit board 100 and surrounding the pixel structures 200 is formed.

Specifically, please refer to FIG. 4E, in step S31, as indicated by arrow A3, a black adhesive 30 is applied (shown in FIG. 4F) on the circuit board 100 so that the black adhesive 30 surrounds the protection layers 220 of the pixel structures 200, as shown in FIG. 4F. The black adhesive 30 may be epoxy resin, silicone, or acrylic, but the present disclosure is not limited thereto. The black adhesive 30 may be dispensed by a nozzle, but the present disclosure is not limited thereto. An applying height of the black adhesive 30 may be greater than or equal to the standard height of the light-emitting diode chip 210 and less than the height of the protection layer 220. Then, please refer to FIG. 4H, in step S32, as indicated by arrow A4, the black adhesive 30 is cured, for example, a thermal curing or ultraviolet curing may be performed. The cured black adhesive 30 forms the light blocking layer 300.

Referring to FIG. 4I, the display module 10 can be obtained after curing the black adhesive.

In summary, the present disclosure provides a display module 10 and a method for manufacturing the same that can reduce the impact of black adhesive misapplication. In the display module 10 according to the present disclosure, the impact of the size of the light-emitting diode chips 210 is reduced because the protection layer is used to isolate the light blocking layer 300 from the light-emitting diode chips 210. As such, no additional selection is required, and both procurement and manufacturing costs can be reduced. Furthermore, the selection of the size of the light-emitting diode chips 210 becomes more flexible, which can enhance customization flexibility. In addition, there is no need to meticulously control the height when dispensing the black adhesive 30, the precision requirements for dispensing equipment can be significantly reduced, and equipment costs can be reduced. Moreover, it is easy to control the thickness of the black adhesive 30, and there is no need to perform subsequent plasma treatment for removing adhesive, which can greatly improve yield and reduce costs.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display module, comprising:
a circuit board;
a plurality of pixel structures disposed on the circuit board, wherein each of the plurality of pixel structures comprises:
a plurality of light-emitting diode chips disposed on the circuit board; and
a protection layer encasing the plurality of light-emitting diode chips; and
a light blocking layer disposed on the circuit board and surrounding the plurality of pixel structures.

2. The display module according to claim 1, wherein the sizes of the plurality of light-emitting diode chips are less than or equal to 250 micrometers (μm).

3. The display module according to claim 1, wherein the plurality of light-emitting diode chips of each of the plurality of pixel structures consist of a red light-emitting diode chip, a green light-emitting diode chip and a blue light-emitting diode chip.

4. The display module according to claim 3, wherein in each of the plurality of pixel structures, the red light-emitting diode chip, the green light-emitting diode chip and the blue light-emitting diode chip are all encased by the same protection layer.

5. The display module according to claim 1, wherein at least two of the plurality of light-emitting diode chips of at least one of the plurality of pixel structures have different heights.

6. The display module according to claim 1, wherein at least two of the plurality of light-emitting diode chips of at least one of the plurality of pixel structures have different lateral sizes.

7. The display module according to claim 1, wherein a distance between two adjacent light-emitting diode chips of the plurality of light-emitting diode chips belonging to the same pixel structure of the plurality of pixel structures is less than a distance between two adjacent light-emitting diode chips of the plurality of light-emitting diode chips belonging to different pixel structures of the plurality of pixel structures.

8. The display module according to claim 1, wherein in each of the plurality of pixel structures, the protection layer directly contacts the plurality of light-emitting diode chips.

9. The display module according to claim 1, wherein the protection layers are bell-shaped.

10. The display module according to claim 1, wherein the protection layers are transparent.

11. The display module according to claim 1, wherein the protection layers are translucent.

12. The display module according to claim 1, wherein a height of the light blocking layer is greater than or equal to a standard height of the plurality of light-emitting diode chips and less than a height of the protection layers.

13. The display module according to claim 1, wherein the light blocking layer directly contacts the protection layers.

14. The display module according to claim 1, wherein the light blocking layer is opaque.

15. A method for manufacturing a display module, comprising:
providing a plurality of light-emitting diode chips of a plurality of pixel structures on a circuit board;
forming a plurality of protection layers to encase the plurality of light-emitting diode chips, wherein each of the plurality of protection layers belongs to a pixel structure of the plurality of pixel structures and encases the plurality of light-emitting diode chips of the pixel structure; and
forming a light blocking layer on the circuit board and surrounding the plurality of pixel structures.

16. The method for manufacturing the display module according to claim 15, wherein forming the plurality of protection layers comprises:
dropping a plurality of liquid droplets of a protection adhesive on the plurality of light-emitting diode chips, wherein each of the plurality of liquid droplets is dropped on the plurality of light-emitting diode chips of one of the plurality of pixel structures; and
curing the plurality of liquid droplets of the protection adhesive.

17. The method for manufacturing the display module according to claim 16, wherein the protection adhesive is epoxy resin or silicone.

18. The method for manufacturing the display module according to claim 16, wherein the cured liquid droplets are bell-shaped.

19. The method for manufacturing the display module according to claim 15, wherein forming the light blocking layer comprises:
applying a black adhesive on the circuit board so that the black adhesive surrounds the plurality of protection layers of the plurality of pixel structures; and
curing the black adhesive.

20. The method for manufacturing the display module according to claim 19, wherein an applying height of the black adhesive is greater than or equal to a standard height of the plurality of light-emitting diode chips and less than a height of the plurality of protection layers.
